(19) United States
(12) Patent Application Publication
(10) Pub. No.: US 2024/0406766 A1
(43) Pub. Date: Dec. 5, 2024

(54) CONTROLLED REDUNDANCY FOR POSITIONING OF EMITTERS OR SENSORS

(71) Applicant: Schlumberger Technology Corporation, Sugar Land, TX (US)

(72) Inventors: Kishore Mulchandani, Henderson, NV (US); Bernard Van Haecke, Mountain View, CA (US)

(21) Appl. No.: 18/735,071

(22) Filed: Jun. 5, 2024

Related U.S. Application Data
(60) Provisional application No. 63/506,159, filed on Jun. 5, 2023.

(51) Int. Cl. H04W 24/04; H04W 64/00

(52) U.S. Cl. CPC H04W 24/04; H04W 64/00

(57) ABSTRACT

Techniques for determining coverage of a plurality of sensors or emitters in a physical environment are presented. The techniques include: providing a computer model of the physical environment; positioning a scope of coverage shape for each sensor or emitter in the model of the physical environment; specifying a required coverage shape; obtaining an indication of a required level of redundancy; iteratively building a graph based on the of scope of coverage shapes and the required coverage shape; pruning the graph based at least on the required level of redundancy; consolidating terminal nodes of the graph to identify a part of the required coverage shape that is not covered by the plurality of sensors or emitters with the required level of redundancy; and outputting a representation of the part of the required coverage shape that is not covered by the plurality of sensors or emitters with the required level of redundancy.

### RELATED APPLICATION

This application claims the benefit of U.S. Provisional Patent Application No. 63/506,159, entitled “Controlled Redundancy for Positioning of Emitters or Sensors,” and filed Jun. 5, 2023, which is hereby incorporated by reference in its entirety.

### FIELD

This disclosure relates generally to placement of emitters or sensors.

### BACKGROUND

Various sensors can have scopes of coverage for which they are effective. Some sensors are omnidirectional, and others may have directional dependence. For example, a cameras may have a field of view, which may take the shape of a frustrum of a pyramid. As another example, some LIDARs can capture and have a scope of coverage of a sphere, while others may have the scope of coverage of a frustum of a cone.

Various lights and other emitters (e.g., infrared emitters) have scopes of coverage in which they are effective. For example, a light source may have a cone within which it provides sufficient illumination.

Existing techniques for determining whether the scopes of coverage of a plurality of emitters sufficiently cover a specified area or volume typically rely on discretizing the area or volume of interest into smaller units, such as pixels, voxels, polygons, or polyhedral, and keeping count of the units based on which of them are covered by an emitter. However, discretization typically results in problems due to under or over sampling, resulting in inaccurate assessments. Further, for large areas or volumes, discretization can get prohibitively expensive in terms of computational time and space. For example, discretizing a typical corridor in a multi-storied building where lights need to be installed into foot sized cubic voxels may result in millions of such cubes. Therefore, discretization is typically impractical for reasonably sized spaces.

### SUMMARY

According to various embodiments, a method determining coverage of a plurality of sensors or emitters in a physical environment is presented. The method includes: providing, in a computer, a model of the physical environment; positioning, in the computer, a respective scope of coverage shape for each sensor or emitter in the model of the physical environment, where a plurality of scope of coverage shapes are positioned; specifying, in the computer, a required coverage shape within the model of the physical environment; obtaining, by the computer, an indication of a required level of redundancy in coverage for the required coverage shape; iteratively building, by the computer, a graph based on the plurality of scope of coverage shapes and the required coverage shape; pruning the graph, by the computer, based at least on the required level of redundancy; consolidating terminal nodes of the graph, by the computer, to identify a part of the required coverage shape that is not covered by the plurality of sensors or emitters with the required level of redundancy; and outputting, by the computer, a representation of the part of the required coverage shape that is not covered by the plurality of sensors or emitters with the required level of redundancy.

Various optional features of the above method embodiments include the following. The method may include arranging the sensors or emitters in the physical environment based on the outputting. The required coverage shape and each of the plurality of scope of coverage shapes may be represented in the computer without discretization. The iteratively building may include including additional levels in the graph using set subtraction and set intersection operations. The including additional levels in the graph may include, for each parent node in a previous level: including a first child node that represents a set represented by the parent node intersected with a scope of coverage shape; and including a second child node that represents a set represented by the parent node subsequent to set subtraction by a scope of coverage shape. The required coverage shape and each of the plurality of scope of coverage shapes may be three dimensional. The pruning the graph, by the computer, may include removing nodes representing null sets. The plurality of sensors or emitters may be mobile, and the method may further include: obtaining, by the computer, an indication of a path of the plurality of sensors or emitters through the physical environment; and repeating the iteratively building, the pruning the graph, and the consolidating leaf nodes of the graph for each of a plurality of locations along the path. The plurality of sensors or emitters may consist of a plurality of sensors. The method may include: determining a quantification of the part of the required coverage shape that is not covered by the plurality of sensors or emitters with the required level of redundancy; and using the quantification as one of a cost function or a reward function of a machine learning process.

According to various embodiments, a system including an electronic processor and a non-transitory persistent memory storing instructions that, when executed by the electronic processor, determine coverage of a plurality of sensors or emitters in a physical environment is presented. The processor performs actions including: providing a model of the physical environment; positioning a respective scope of coverage shape for each sensor or emitter in the model of the physical environment, where a plurality of scope of coverage shapes are positioned; specifying a required coverage shape within the model of the physical environment; obtaining an indication of a required level of redundancy in coverage for the required coverage shape; iteratively building a graph based on the plurality of scope of coverage shapes and the required coverage shape; pruning the graph based at least on the required level of redundancy; consolidating terminal nodes of the graph to identify a part of the required coverage shape that is not covered by the plurality of sensors or emitters with the required level of redundancy; and outputting a representation of the part of the required coverage shape that is not covered by the plurality of sensors or emitters with the required level of redundancy.

Various optional features of the above system embodiments include the following. The actions may further include arranging the sensors or emitters in the physical environment based on the outputting. The required coverage shape and each of the plurality of scope of coverage shapes may be represented without discretization. The iteratively building may include including additional levels in the graph using set subtraction and set intersection operations. The including additional levels in the graph may include, for each parent node in a previous level: including a first child node that represents a set represented by the parent node intersected with a scope of coverage shape; and including a second child node that represents a set represented by the parent node subsequent to set subtraction by a scope of coverage shape. The required coverage shape and each of the plurality of scope of coverage shapes may be three dimensional. The pruning the graph may include removing nodes representing null sets. The plurality of sensors or emitters may be mobile, and the actions may further include: obtaining an indication of a path of the plurality of sensors or emitters through the physical environment; and repeating the iteratively building, the pruning the graph, and the consolidating leaf nodes of the graph for each of a plurality of locations along the path. The plurality of sensors or emitters may consist of a plurality of sensors. The actions may further include: determining a quantification of the part of the required coverage shape that is not covered by the plurality of sensors or emitters with the required level of redundancy; and using the quantification as one of a cost function or a reward function of a machine learning process.

Combinations, (including multiple dependent combinations) of the above-described elements and those within the specification have been contemplated by the inventors and may be made, except where otherwise indicated or where contradictory.

### BRIEF DESCRIPTION OF THE DRAWINGS

Various features of the examples can be more fully appreciated, as the same become better understood with reference to the following detailed description of the examples when considered in connection with the accompanying figures, in which:

FIG. 1 is a schematic diagram of a portion of a corridor depicting an arrangement of sensors or emitters and their respective scope of coverage shapes according to various embodiments;

FIG. 2 is a schematic diagram of a swept scope of coverage shape for a mobile sensor or emitter according to various embodiments;

FIG. 3 is a diagram of a binary tree for determining coverage of a plurality of sensors or emitters in a physical environment according to various embodiments;

FIG. 4 is a schematic diagram of two scope of coverage shapes for sensors or emitters in a required coverage rectangle according to various embodiments;

FIG. 5 is a flow diagram for a method of determining coverage of a plurality of sensors or emitters in a physical environment according to various embodiments; and

FIG. 6 is a schematic diagram of a computer system suitable for implementing the method of FIG. 5.

### DESCRIPTION OF THE EXAMPLES

Reference will now be made in detail to example implementations, illustrated in the accompanying drawings. Wherever convenient, the same reference numbers will be used throughout the drawings to refer to the same or like parts. In the following description, reference is made to the accompanying drawings that form a part thereof, and in which is shown by way of illustration specific exemplary embodiments in which the disclosure may be practiced. These examples are described in sufficient detail to enable those skilled in the art to practice and it is to be understood that other examples may be utilized and that changes may be made without departing from the scope described. The following description is, therefore, merely exemplary.

Some embodiments provide techniques for determining the regions covered by sensors or emitters with a specified level of redundancy, as well as the regions that are not so covered. In general, sensors or emitters may be located to cover a defined region with a required level of redundancy. For example, within a facility, such as a building, sensors or emitters may be located to cover locations of importance. Further, the sensors or emitters may be located to ensure redundancy, so that failure of one or more sensors or emitters does not affect the total required coverage. Some embodiments provide techniques for receiving a user specified region of coverage and a required redundancy, and for determining whether a particular arrangement of sensors or emitters provides the specified coverage with the required redundancy. According to various embodiments, the regions may be in any dimension, such as by way of non-limiting example, two dimensional areas or three dimensional volumes. According to various embodiments, the sensors or emitters may be stationary, e.g., installed in a facility.

Some embodiments utilize a non-discretizing technique for solving the problem of determining regions covered and not covered by sensors or emitters with a specified level of redundancy. According to some embodiments, set operations, such as Boolean union, subtractions, and intersection operations, may be used to solve the problem. Moreover, the shapes representing required coverage and the shapes representing the scope of coverage of the sensors or emitters may be represented continuously in a computer, thereby avoiding discretization. These representations and operations are used in CAD (Computer Aided Design) modeling software, for example, to design shapes of various parts and assemblies.

According to various embodiments, the sensors or emitters may be mobile, e.g., mounted on a robot. According to some embodiments, paths of mobile sensors or emitters may be determined so that the sensors or emitters provide a specified coverage with a required redundancy.

Some embodiments may be used to determine optimal sensor or emitter placement or pathways. Here, “optimal” means desirable, or meeting specified criteria, as opposed to necessarily being superior to all other placements or pathways.

Embodiments are amenable to a wide variety of use cases, including, by way of non-limiting examples, the following:
In operations, during autonomous inspections, an embodiment may be used to assess a path a sensor (or sensors) mounted on a robot must take to cover a certain inspection volume or area;
An embodiment may be used to assess locations for mounting cameras or other types of sensors in a facility to monitor all the sensitive zones;
An embodiment may be used to position and/or orient lights in a corridor or hall of a facility;
An embodiment may be used to mount motion sensors in a facility to detect intrusion in all the sensitive areas;
An embodiment may be used to mount in areas forbidden or dangerous;
An embodiment may be used to determine a configuration of fixed viewpoints for optimal optical analysis of a 3-D asset, such as a drill bit;
An embodiment may be used to compute an optimal path for one or more robotic platforms to capture 3D information from an asset in a facility.

An embodiment may be used to install an optimal number of sensors in a facility, e.g., cameras, motion sensors etc., to guarantee coverage and fault tolerance, in such a way that capital or operating expenditures are minimized. Installing expensive sensors where they do not provide any extra benefits, because the areas are already adequately covered, results in a low return on investment. Thus, an embodiment may be used avoid over-redundancy and keep costs within budgets.

These and other features and advantages are set forth herein in reference to the figures.

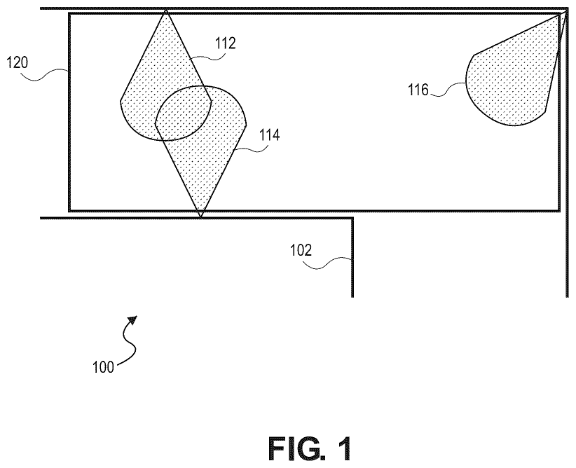

FIG. 1 is a schematic diagram 100 of a portion of a corridor 102 depicting an arrangement of sensors or emitters and their respective scope of coverage shapes 112, 114, 116 according to various embodiments. Although a corridor 102 is depicted in FIG. 1, in general, any physical space, e.g., inside or outside of a building.

According to various embodiments, each sensor or emitter may be of any of a variety of types. By way of non-limiting examples, sensor types contemplated according to various embodiments include: motion sensors (e.g., infrared, acoustic, etc.), Light Detection and Ranging (LIDAR), cameras (e.g., visible light, infrared, etc.; still, video, etc.), etc. By way of non-limiting examples, emitter types contemplated according to various embodiments include: visible light emitters (e.g., floodlights, LEDs, etc.), infrared emitters (e.g., heat lamps, night vision illuminators, etc.), etc.

According to various embodiments, sensors may be compound. That is, some sensors may have multiple sub-sensors, such as in the case of an array of sensors that work collectively. Stereo cameras are an example, where two cameras are both used, each covering a section with overlaps. According to various embodiments, a compound sensor may be considered as a single sensor and associated with a corresponding scope of coverage shape.

Each sensor or emitter has an associated scope of coverage shape. As shown in the diagram 100, the scope of coverage shapes 112, 114, 116 are triangles capped with semi-circles. However, these scope of coverage shapes are non-limiting examples. Other two-dimensional scope of coverage shapes include, by way of non-limiting examples: triangles, circles, semicircles, ovals, squares, polygons, etc.

In general, scope of coverage shapes according to various embodiments are not limited to two-dimensional shapes. According to some embodiments, scope of coverage shapes may be three-dimensional. Possible three-dimensional scope of coverage shapes include, by way of non-limiting examples: cones, pyramids, frustrums of a cone, frustrums of a pyramid, spheres, ovoids, cubes, parallelepipeds, polyhedrons, etc.

Note that in general, a scope of coverage shape need not be contiguous. For example, there could be a “blind spot” in coverage due to the mounting of the sensors or obstructions.

Also shown in FIG. 1 is a required coverage shape 120. The required coverage shape 120 defines where the sensors or emitters are intended to cover. In general, a required coverage shape may be any shape, not limited to a rectangle as shown in FIG. 1. Further, in general, a required coverage shape may be in any number of dimensions, e.g., two-dimensional or three-dimensional. Yet further, a required coverage shape need not be contiguous. For example, a required coverage shape may cover part of a corridor and an adjacent room, where the two areas do not intersect.

According to various embodiments, the scope of coverage shapes and/or the required coverage shape are represented continuously in a computer, thereby avoiding discretization (e.g., rasterization). The representation may be in any of a variety of forms, e.g., vector representation, parametric curves or surfaces, analytical math equations, polygon or polyhedron parameterization (e.g., for a circle, a specification of a center and radius), etc. In general, the representation of the coverage shapes and/or the required coverage shape may be relatively tiny in the computer and not consume additional memory as their size increases (e.g., as opposed to with discretization representations).

In general, multiple levels of redundancy are contemplated. For example, portions of two, three, four, or more scope of coverage shapes may overlap, providing regions with levels of redundancy of two, three, four, or more. Further, a user specify a required level of redundancy for coverage of the required coverage shape 120, requiring that the entirety of the required coverage shape be covered with the specified level of redundancy by the scope of coverage shapes.

Note that, as shown in the diagram 100, the required coverage shape 120 is not fully covered by the scope of coverage shapes 112, 114, 116. Much of the required coverage shape 120 has no coverage. Further, only a small area of the required coverage shape 120 has overlapping redundant coverage. In particular, the area of overlap between the scope of coverage shapes 112, 114 provides an area of two-level redundant coverage.

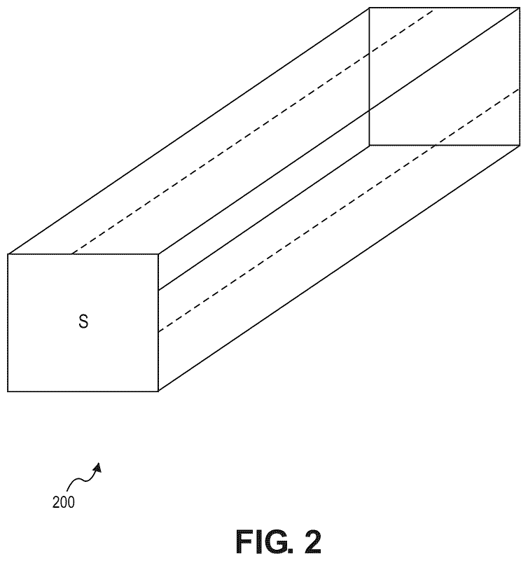

Embodiments are not limited to stationary sensors or emitters. Some embodiments may be used for moving sensors or emitters. According to some such embodiments, the sensor or emitter at various times may be treated as a separate sensor or emitter. For example, the scope of coverage shapes may be repositioned periodically, e.g., once per second, along a defined path or paths. Thus, time (but not space) may be discretized. The shapes of coverage with the required redundancy may be determined at each step of the temporal discretization and combined (e.g., using the set union operation) to determine a total shape of coverage with the required redundancy along the path. Alternately, a scope of coverage shape of a mobile sensor or emitter may be represented as a single continuous scope of coverage shape, as shown and described presently in reference to FIG. 2.

FIG. 2 is a schematic diagram of a swept scope of coverage shape 200 for a mobile sensor or emitter according to various embodiments. In general, in the case where a sensor or emitter is moving, the scope of coverage shape for the sensor or emitter may be represented by sweeping the stationary shape along the path. This results in a swept area for a two-dimensional scope of coverage shape or a swept volume for a three-dimensional scope of coverage shape. According to some embodiments, an analytical sweep or “extrusion” operation is performed to represent the resulting swept scope of coverage shape. This technique is particularly applicable where, for example, a sensor is continuously capturing readings, in which case the coverage area is continuous. As shown in FIG. 2, the swept scope of coverage shape 200 results from sweeping the original stationary square scope of coverage shape S along a straight path.

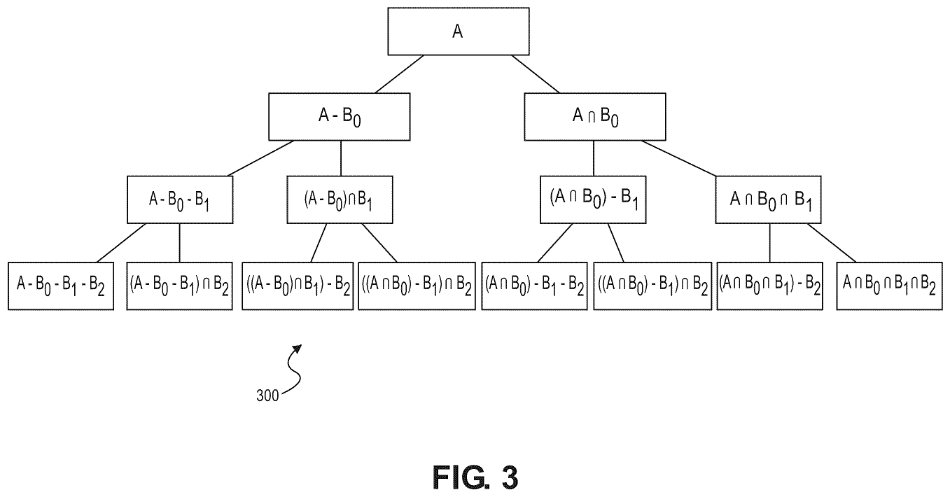

FIG. 3 is a diagram of a binary tree 300 for determining coverage of a plurality of sensors or emitters in a physical environment according to various embodiments. Although a binary tree 300 is depicted in FIG. 3, embodiments are not limited to binary trees or trees in general. According to various embodiments, any graph with edges and nodes may be used, not limited to trees. Nevertheless, for purposes of illustration rather than limitation, embodiments are described herein in reference to the binary tree 300.

Some embodiments utilize an iterative process as described presently. For purposes of notation, denote a required coverage shape, which may be in any dimension, as A. For a plurality of n sensors or emitters, denote the scope of coverage shape of the i-th sensor as Bᵢ. Thus, for the n sensors or emitters, the individual scope of coverage shapes for each sensor or emitter may be represented as B₀, B₁, . . . , Bₙ₋₁. The list of sensors or emitters may be arranged in any order for the iterative process described herein. Starting with the required shape of coverage A, for each additional sensor or emitter considered, Boolean subtract its area or volume. Thus, the area or volume remaining after n sensors or emitters may be represented as, by way of non-limiting example: SUBTRACT (A, UNION (Bᵢ where i=0, 1, . . . , n−1)). If this operation represents the empty set, then A has been fully covered.

The above example is appropriate for a single level of coverage. However, embodiments may be used to ensure two or more redundant levels of coverage. Accordingly, for fault tolerance, these set operations may be used to construct a binary tree as follows. Instead of subtracting for the first sensor, as a first step the set A may be split into SUBTRACT (A, B₀) and INTERSECT (A, B₀). These pieces may be represented as nodes in a graph, e.g., a binary tree.

For the next step in the iteration, the next sensor scope of coverage shape B₁ will operate on these two pieces to generate the following pieces, which may be represented as nodes in the binary tree, as follows: (1) SUBTRACT (SUBTRACT (A, B₀), B₁); (2), INTERSECT (SUBTRACT (A, B₀), B₁); (3) SUBTRACT (INTERSECT (A, B₀), B₁); and (4) INTERSECT (INTERSECT (A, B₀), B₁).

This pattern of operations may be continued for each additional sensor or emitter scope of coverage shape. At each additional step in the iteration, thus for each additional scope of coverage shape, two additional child nodes below each existing parent node are defined. Thus, a binary tree such as the binary tree 200 may be generated.

However, not every node of the tree will yield a child node for purposes of assessing coverage with a required level of redundancy. For example, a node may represent a shape that is either be empty or that has reached the required level of redundancy. Thus, the tree may be pruned to remove such terminal nodes, which may be leaves in the case of a binary tree. In particular, the tree may be pruned to remove a node if the node either represents an empty set or if node represents a shape that has as many INTERSECTs as the required level of redundancy (R). For example, if R=1, then INTERSECT (A, B₀) is removed, if R=2, INTERSECT (INTERSECT (A, B₀), B₁) is removed, etc.

The nodes that remain after all of the terminal nodes have been processed represent the place or places that do not have the required level of redundancy R. Taking the ratio of the area (or volume) of these pieces over the total area (or volume) of the gives the proportion (e.g., percentage) not covered with the required level of redundancy. Subtracting this proportion from a total (e.g., 1) gives the proportion (e.g., percentage) that is covered with the required level of redundancy.

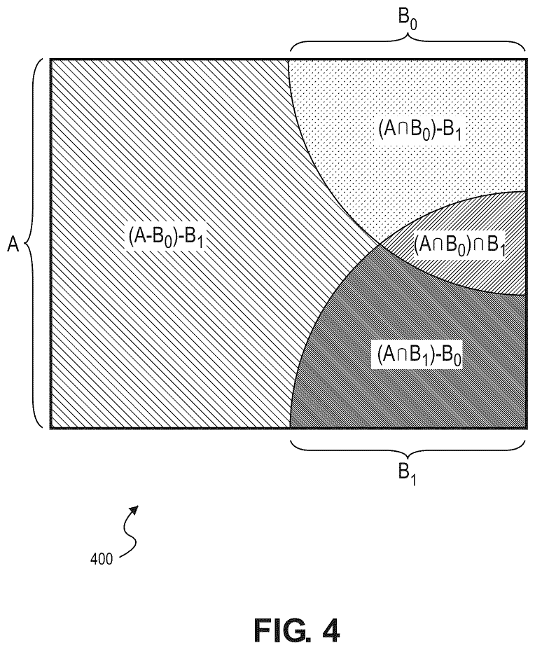

The set operations described above are described in detail by way of an example in reference to FIG. 4, presently.

FIG. 4 is a schematic diagram 400 of two scope of coverage shapes for sensors or emitters in a required coverage rectangle according to various embodiments. In particular, FIG. 4 depicts a rectangular required coverage shape A and two scope of coverage shapes B₀ and B₁. The regions defined by the following operations are shown in FIG. 4: (A−B₀)−B₁, (A∩B₀)−B₁, (A∩B₁)−B₀, and (A∩B₀)∩B₁. Note that although FIG. 4 depicts two-dimensional shapes, embodiments are not so limited. The set operations as disclosed herein work in any number of dimensions.

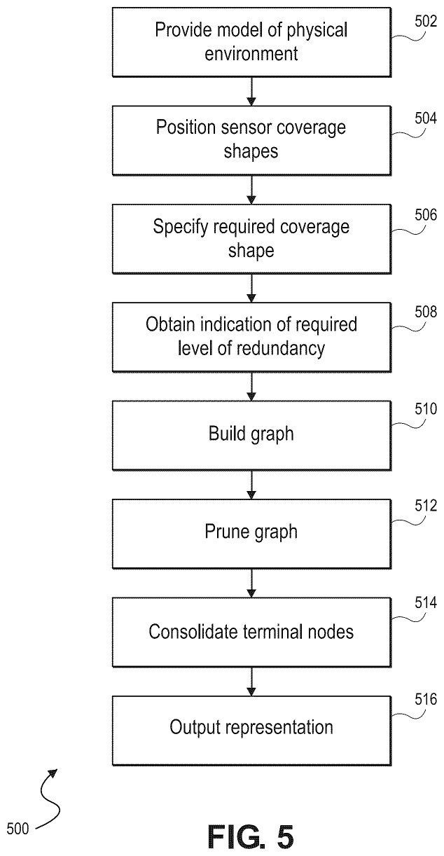

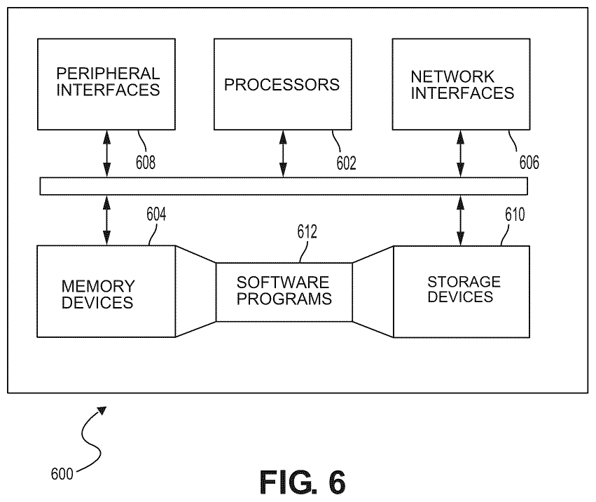

FIG. 5 is a flow diagram for a method 500 of determining coverage of a plurality of sensors or emitters in a physical environment according to various embodiments. The method 500 may be implemented in part by a computing system, e.g., as described in FIG. 6.

At 502, the method 500 includes providing, in a computer, a model of the physical environment. By way of non-limiting example, the model may be provided by a user entering a floorplan of a building or building portion, for example. The model may be represented in a computer aided design program, for example.

At 504, the method 500 includes positioning, in the computer, a respective scope of coverage shape for each sensor or emitter in the model of the physical environment. By way of non-limiting example, the actions of 504 may include a user placing the shape of coverage shapes in the model of the physical environment, e.g., within a computer aided design program. The shape of coverage shapes may be in any of the forms shown and described herein in reference to FIG. 1, for example.

At 506, the method 500 includes specifying, in the computer, a required coverage shape within the model of the physical environment. By way of non-limiting example, the actions of 506 may include a user placing the required coverage shape in the model of the physical environment, e.g., within a computer aided design program. The required coverage shape may be in any of the forms shown and described herein in reference to FIG. 1, for example.

At 508, the method 500 includes obtaining, by the computer, an indication of a required level of redundancy in coverage for the required coverage shape. The actions of 508 may include a user entering the indication of the required level of redundancy, which may be in the form of a numeral, e.g., 1 (indicating no required redundancy), 2, 3, etc.

At 510, the method 500 includes iteratively building, by the computer, a graph based on the plurality of scope of coverage shapes and the required coverage shape. The graph may be in the form of a binary tree, by way of non-limiting example. The graph may be built as shown and described herein in reference to FIGS. 2 and 3, by way of non-limiting example.

At 512, the method 500 includes pruning the graph, by the computer, based at least on the required level of redundancy. The graph may be pruned by removing certain terminal nodes, such as certain leaf nodes in the case that the graph is a tree. For example, the graph may be pruned by removing terminal nodes that correspond to the required level of redundancy, for example. The graph may be pruned as shown and described herein in reference to FIG. 2, for example.

At 514, the method 500 includes consolidating terminal nodes of the graph, by the computer, to identify a part of the required coverage shape that is not covered by the plurality of sensors or emitters with the required level of redundancy. The actions of 514 may include, by way of non-limiting example, joining (e.g., using the set union operation) shapes represented by the terminal nodes in the graph after the pruning of 512. The consolidating may include identifying the terminal nodes in a data structure, for example.

At 516, the method 500 includes outputting, by the computer, a representation of the part of the required coverage shape that is not covered by the plurality of sensors or emitters with the required level of redundancy. The outputting may take any of a variety of forms. According to some embodiments, the representation may be displayed graphically, e.g., in a computer aided design environment. The representation may include a display of a shape that is, or is not, covered with the required level of redundancy. The graphical display may distinguish, e.g., by color or pattern, shapes that have different levels of redundancies of coverage.

According to some embodiments, the representation includes a quantification. For example, the representation may include a numeric proportion (e.g., percentage) of the required coverage shape that is covered with the required level of redundancy, or the numeric proportion (e.g., percentage) that is not so covered.

In general, the representation may be output by display on a screen, or provided to a different system of process. For an example of the latter, the representation may be used in a machine learning system as a cost or reward function value.

Many variations, modifications, and uses of the embodiments explicitly disclosed herein are possible, some of which are disclosed presently.

According to various embodiments, a shape of coverage for a sensor or emitter may be truncated to account for various phenomena, such as obstructions. This truncation may occur in two or three dimensions, by way of non-limiting examples. For example, for cameras, the viewing frustum of a camera may be truncated to account for an obstruction, such as a corner of a hallway or a pillar that obstructs the view of the areas/volume behind it. As another example, for lights, the pillar may cast a shadow on areas behind it, which may be accounted for by truncating the associated shapes of coverage.

The truncation described above may be accomplished through the use of an obstruction shape, which may be in two or three dimensions, for example. The obstruction shape may be represented symbolically as E. Each sensor or emitter Bᵢ may have an associated obstruction shape Eᵢ, each of which may account for one or more obstruction. As a pre-processing step, the scope of coverage shapes may be processed to account for obstructions, e.g., for every i, i=0, . . . , n−1, Bᵢ:=SUBTRACT (Bᵢ, Eᵢ). This preprocessing step sets up all sensor or emitter area/volumes to be only what they can actually cover in the physical environment, as opposed to their theoretical coverage.

Some embodiments may be used to optimize sensor or emitter placement (for stationary sensors or emitters) or pathways (for mobile sensors or emitters).

For example, for stationary sensors, a plurality of possible sensor or emitter location configurations may be evaluated using an embodiment, and the sensor or emitter location configuration with the largest coverage with the required level of redundancy selected for actual sensor or emitter placement. The plurality of possible sensor or emitter location configurations may be obtained using any of a variety of techniques, including manual specification and/or automatic generation. For automatic generation, the sensor or emitter locations may be selected randomly, procedurally, or determined by perturbation of a previous or alternate sensor or emitter location configuration.

As another example, for mobile sensors, a plurality of possible sensor or emitter pathways may be evaluated using an embodiment, and the sensor or emitter pathway with the largest coverage with the required level of redundancy selected as the actual pathway. The plurality of possible sensor or emitter pathways may be obtained using any of a variety of techniques, including manual specification and/or automatic generation. For automatic generation, the sensor or emitter pathways may be selected randomly, procedurally, or determined by perturbation of a previous or alternate sensor or emitter pathway.

According to some embodiments, a quantification of the part of the required coverage shape that is, or is not, covered by the plurality of sensors or emitters with the required level of redundancy may be used for a cost or reward function in a machine learning algorithm. According to such embodiments, the machine learning algorithm may be trained to provide an optimal sensor or emitter placement (for stationary sensors or emitters) or an optimal sensor or emitter pathway (for mobile sensors or emitters).

FIG. 6 illustrates a schematic view of a computing or processor system 600, according to an embodiment. The system 600 may be used to implement various methods disclosed herein, e.g., as shown and described in reference to FIG. 5. The processor system 600 may include one or more processors 602 of varying core configurations (including multiple cores) and clock frequencies. The one or more processors 602 may be operable to execute instructions, apply logic, etc. It will be appreciated that these functions may be provided by multiple processors or multiple cores on a single chip operating in parallel and/or communicably linked together. In at least one embodiment, the one or more processors 602 may be or include one or more GPUs.

The processor system 600 may also include a memory system, which may be or include one or more memory devices and/or computer-readable media 604 of varying physical dimensions, accessibility, storage capacities, etc. such as flash drives, hard drives, disks, random access memory, etc., for storing data, such as images, files, and program instructions for execution by the processor 602. In an embodiment, the computer-readable media 604 may store instructions that, when executed by the processor 602, are configured to cause the processor system 600 to perform operations. For example, execution of such instructions may cause the processor system 600 to implement one or more portions and/or embodiments of the methods described herein.

The processor system 600 may also include one or more network interfaces 606. The network interfaces 606 may include any hardware, applications, and/or other software. Accordingly, the network interfaces 606 may include Ethernet adapters, wireless transceivers, PCI interfaces, and/or serial network components, for communicating over wired or wireless media using protocols, such as Ethernet, wireless Ethernet, etc.

The processor system 600 may further include one or more peripheral interfaces 608, for communication with a display screen, projector, keyboards, mice, touchpads, sensors, other types of input and/or output peripherals, and/or the like. In some implementations, the components of processor system 600 need not be enclosed within a single enclosure or even located in close proximity to one another, but in other implementations, the components and/or others may be provided in a single enclosure.

The memory device 604 may be physically or logically arranged or configured to store data on one or more storage devices 610. The storage device 610 may include one or more file systems or databases in any suitable format. The storage device 610 may also include one or more software programs 612, which may contain interpretable or executable instructions for performing one or more of the disclosed processes. When requested by the processor 602, one or more of the software programs 612, or a portion thereof, may be loaded from the storage devices 610 to the memory devices 604 for execution by the processor 602.

Those skilled in the art will appreciate that the above-described componentry is merely one example of a hardware configuration, as the processor system 600 may include any type of hardware components, including any necessary accompanying firmware or software, for performing the disclosed implementations. The processor system 600 may also be implemented in part or in whole by electronic circuit components or processors, such as application-specific integrated circuits (ASICs) or field-programmable gate arrays (FPGAs).

Certain examples can be performed using a computer program or set of programs. The computer programs can exist in a variety of forms both active and inactive. For example, the computer programs can exist as software program(s) comprised of program instructions in source code, object code, executable code or other formats; firmware program(s), or hardware description language (HDL) files. Any of the above can be embodied on a transitory or non-transitory computer readable medium, which include storage devices and signals, in compressed or uncompressed form. Exemplary computer readable storage devices include conventional computer system RAM (random access memory), ROM (read-only memory), EPROM (erasable, programmable ROM), EEPROM (electrically erasable, programmable ROM), and magnetic or optical disks or tapes.

Aspects of the present disclosure are described herein with reference to flowchart illustrations and/or block diagrams of methods, apparatus (systems), and computer program products according to embodiments of the disclosure. It will be understood that each block of the flowchart illustrations and/or block diagrams, and combinations of blocks in the flowchart illustrations and/or block diagrams, can be implemented using computer readable program instructions that are executed by an electronic processor.

These computer readable program instructions may be provided to a processor of a general-purpose computer, special purpose computer, or other programmable data processing apparatus to produce a machine, such that the instructions, which execute via the electronic processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

In embodiments, the computer readable program instructions may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the C programming language or similar programming languages. The computer readable program instructions may execute entirely on a user's computer, partly on the user's computer, as a stand-alone software package, partly on the user's computer and partly on a remote computer or entirely on the remote computer or server.

As used herein, the terms “A or B” and “A and/or B” are intended to encompass A, B, or {A and B}. Further, the terms “A, B, or C” and “A, B, and/or C” are intended to encompass single items, pairs of items, or all items, that is, all of: A, B, C, {A and B}, {A and C}, {B and C}, and {A and B and C}. The term “or” as used herein means “and/or.”

As used herein, language such as “at least one of X, Y, and Z,” “at least one of X, Y, or Z,” “at least one or more of X, Y, and Z,” “at least one or more of X, Y, or Z,” “at least one or more of X, Y, and/or Z,” or “at least one of X, Y, and/or Z,” is intended to be inclusive of both a single item (e.g., just X, or just Y, or just Z) and multiple items (e.g., {X and Y}, {X and Z}, {Y and Z}, or {X, Y, and Z}). The phrase “at least one of” and similar phrases are not intended to convey a requirement that each possible item must be present, although each possible item may be present.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ”, it is intended that such elements are to be interpreted under 35 U.S.C. § 112 (f). However, for any claims containing elements designated in any other manner, it is intended that such elements are not to be interpreted under 35 U.S.C. § 112 (f).

While the disclosure has been described with reference to the exemplary embodiments thereof, those skilled in the art will be able to make various modifications to the described examples without departing from the true spirit and scope. The terms and descriptions used herein are set forth by way of illustration only and are not meant as limitations. In particular, although the method has been described by examples, the steps of the method can be performed in a different order than illustrated or simultaneously. Those skilled in the art will recognize that these and other variations are possible within the spirit and scope as defined in the following claims and their equivalents.

What is claimed is:

1. A method of determining coverage of a plurality of sensors or emitters in a physical environment, the method comprising:
providing a model of the physical environment;
positioning a respective scope of coverage shape for each sensor or emitter in the model of the physical environment, wherein a plurality of scope of coverage shapes are positioned;
specifying a required coverage shape within the model of the physical environment;
obtaining an indication of a required level of redundancy in coverage for the required coverage shape;
iteratively building a graph based on the plurality of scope of coverage shapes and the required coverage shape;
pruning the graph based at least on the required level of redundancy;
consolidating terminal nodes of the graph to identify a part of the required coverage shape that is not covered by the plurality of sensors or emitters with the required level of redundancy; and
outputting a representation of the part of the required coverage shape that is not covered by the plurality of sensors or emitters with the required level of redundancy.

2. The method of claim 1, further comprising arranging the sensors or emitters in the physical environment based on the outputting.

3. The method of claim 1, wherein the required coverage shape and each of the plurality of scope of coverage shapes are represented in the computer without discretization.

4. The method of claim 1, wherein the iteratively building comprises including additional levels in the graph using set subtraction and set intersection operations.

5. The method of claim 4, wherein the including additional levels in the graph comprises, for each parent node in a previous level:
including a first child node that represents a set represented by the parent node intersected with a scope of coverage shape; and
including a second child node that represents a set represented by the parent node subsequent to set subtraction by a scope of coverage shape.

6. The method of claim 1, wherein the required coverage shape and each of the plurality of scope of coverage shapes are three dimensional.

7. The method of claim 1, wherein the pruning the graph, by the computer, further comprises removing nodes representing null sets.

8. The method of claim 1, wherein the plurality of sensors or emitters are mobile, the method further comprising:
obtaining, by the computer, an indication of a path of the plurality of sensors or emitters through the physical environment; and
repeating the iteratively building, the pruning the graph, and the consolidating leaf nodes of the graph for each of a plurality of locations along the path.

9. The method of claim 8, wherein the plurality of sensors or emitters consists of a plurality of sensors.

10. The method of claim 1, further comprising:
determining a quantification of the part of the required coverage shape that is not covered by the plurality of sensors or emitters with the required level of redundancy; and
using the quantification as one of a cost function or a reward function of a machine learning process.

11. A system comprising an electronic processor and a non-transitory persistent memory storing instructions that, when executed by the electronic processor, determine coverage of a plurality of sensors or emitters in a physical environment by performing actions comprising:
providing a model of the physical environment;
positioning a respective scope of coverage shape for each sensor or emitter in the model of the physical environment, wherein a plurality of scope of coverage shapes are positioned;
specifying a required coverage shape within the model of the physical environment;
obtaining an indication of a required level of redundancy in coverage for the required coverage shape;
iteratively building a graph based on the plurality of scope of coverage shapes and the required coverage shape;
pruning the graph based at least on the required level of redundancy;
consolidating terminal nodes of the graph to identify a part of the required coverage shape that is not covered by the plurality of sensors or emitters with the required level of redundancy; and
outputting a representation of the part of the required coverage shape that is not covered by the plurality of sensors or emitters with the required level of redundancy.

12. The system of claim 11, wherein the actions further comprise arranging the sensors or emitters in the physical environment based on the outputting.

13. The system of claim 11, wherein the required coverage shape and each of the plurality of scope of coverage shapes are represented without discretization.

14. The system of claim 11, wherein the iteratively building comprises including additional levels in the graph using set subtraction and set intersection operations.

15. The system of claim 14, wherein the including additional levels in the graph comprises, for each parent node in a previous level:
including a first child node that represents a set represented by the parent node intersected with a scope of coverage shape; and
including a second child node that represents a set represented by the parent node subsequent to set subtraction by a scope of coverage shape.

16. The system of claim 11, wherein the required coverage shape and each of the plurality of scope of coverage shapes are three dimensional.

17. The system of claim 11, wherein the pruning the graph further comprises removing nodes representing null sets.

18. The system of claim 11, wherein the plurality of sensors or emitters are mobile, the actions further comprising:
obtaining an indication of a path of the plurality of sensors or emitters through the physical environment; and
repeating the iteratively building, the pruning the graph, and the consolidating leaf nodes of the graph for each of a plurality of locations along the path.

19. The system of claim 18, wherein the plurality of sensors or emitters consists of a plurality of sensors.

20. A method of placing a plurality of sensors or emitters in a physical environment to achieve coverage with a specified level of redundancy, the method comprising:
providing a model of the physical environment;
positioning a respective scope of coverage shape for each sensor or emitter in the model of the physical environment, wherein a plurality of scope of coverage shapes are positioned, wherein each of the plurality of scope of coverage shapes are represented in the computer using one of: vector representation, parametric curve representation, parametric surface representation, analytical equation representation, polygon parameterization, or polyhedron parameterization;
specifying a required coverage shape within the model of the physical environment, wherein the required coverage shape is represented in the computer using one of: vector representation, parametric curve representation, parametric surface representation, analytical equation representation, polygon parameterization, or polyhedron parameterization;
obtaining an indication of a required level of redundancy in coverage for the required coverage shape;
iteratively building a binary tree, wherein the iteratively building comprises adding additional levels in the binary tree by, for each parent node in a previous level of the binary tree,
adding a first child node that represents a set represented by the parent node intersected with a scope of coverage shape of the plurality of scope of coverage shapes, and
adding a second child node that represents a set represented by the parent node subsequent to set subtraction by a scope of coverage shape of the plurality of scope of coverage shapes;
pruning the binary tree based at least on the required level of redundancy;
consolidating terminal nodes of the binary tree to identify a part of the required coverage shape that is not covered by the plurality of sensors or emitters with the required level of redundancy;
outputting a representation of the part of the required coverage shape that is not covered by the plurality of sensors or emitters with the required level of redundancy; and
arranging the sensors or emitters in the physical environment based on the outputting.
